(19) United States
(12) Patent Application Publication
(10) Pub. No.: US 2010/0164001 A1
(43) Pub. Date: Jul. 1, 2010

(54) Implant process for blocked salicide poly resistor and structures formed thereby

(76) Inventors: Joodong Park, Portland, OR (US); Chia-Hong Jan, Portland, OR (US); Lisa M. McGill, Hillsboro, OR (US)

Correspondence Address: INTEL CORPORATION;c/o CPA Global, P.O. BOX 52050, MINNEAPOLIS, MN, 55402, US

(21) Appl. No.: 12/319,015

(22) Filed: Dec. 30, 2008

(51) Int. Cl. H01L 27/092; H01L 21/8238; H01L 21/22

(52) U.S. Cl. 257/369; 438/229; 438/238; 438/514; 257/E27.062; 257/E21.135; 257/E21.632

(57) ABSTRACT

Methods and associated structures of forming a microelectronic device are described. Those methods may include implanting an exposed p type silicon portion of a substrate with a carbon species, wherein endcap regions of a blocked salicide resistor and a p type structure that are both disposed on the exposed p type silicon portion of the substrate are implanted with the carbon species.

### BACKGROUND OF THE INVENTION

Blocked salicide polysilicon resistors (BSR) may contain salicided endcap regions at both ends of the BSR. BSR matching behavior is strongly governed by matching of the salicide at these endcap regions. BSR matching can be challenging when the thermal budget of the salicide processing techniques (for example, rapid thermal processing (RTA) salicide processing that may be used for salicide formation, salicide anneal, etc.) is limited.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1f represent structures according to embodiments of the present invention.

FIG. 1g depicts a graph according to embodiments of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure are described. Those methods may include implanting an exposed p type silicon portion of a substrate with a carbon species, wherein endcap regions of a blocked salicide resistor and a p type structure that are both disposed on the exposed p type silicon portion of the substrate are implanted with the carbon species. Methods of the present invention enable the improvement of BSR matching, without n+salicide degradation.

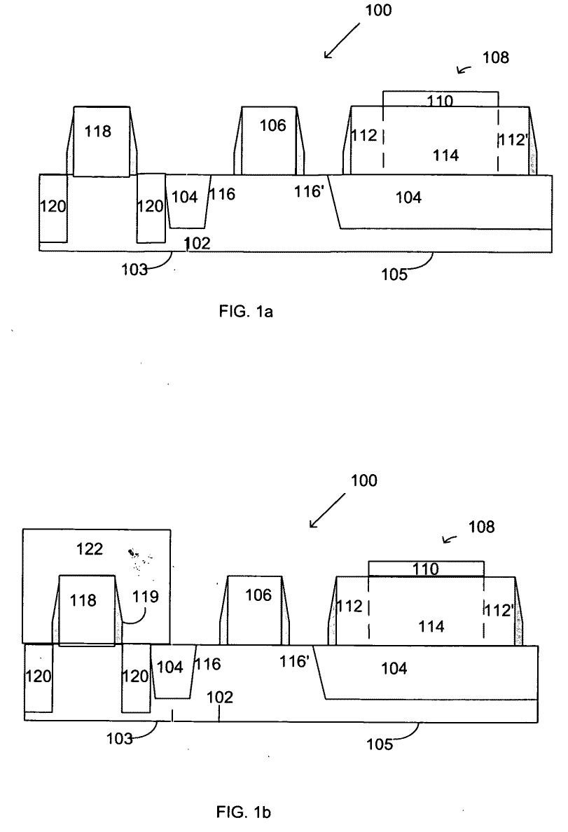

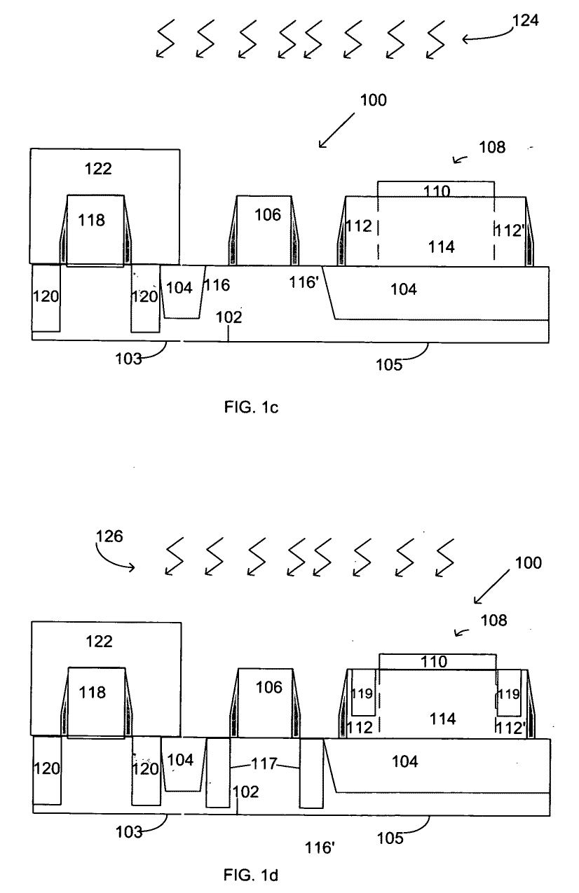

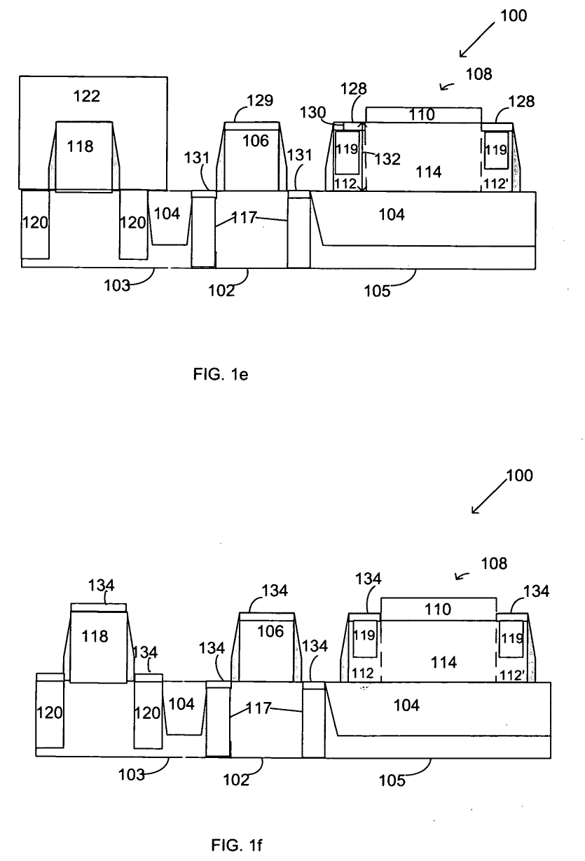

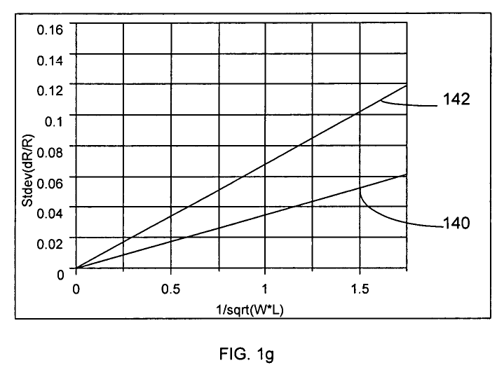

Methods of the present invention are depicted in FIGS. 1a-1h. FIG. 1a shows a cross section of a portion of a structure 100, such as a transistor structure, for example, which may comprise a substrate 102. The substrate 102 may be comprised of materials such as, but not limited to, silicon, silicon-on-insulator, germanium, indium antimonide, lead telluride, indium arsenide, indium phosphide, gallium arsenide, gallium antimonide, or combinations thereof.

The substrate 102 may comprise an n type silicon portion 103 and a p type silicon portion 105, that may be isolated from each other by an isolation material 104, such as a dielectric material, which in some cases may comprise a shallow trench isolation (STI) material 104. In an embodiment, the n type silicon portion 103 and the p type silicon portion 105 may comprise portions of NMOS and PMOS transistor structures, respectively.

The n type silicon portion 103 of the substrate 102 may comprise an NMOS gate 118, and implanted NMOS source/drain regions 120, which may be previously implanted by NMOS source/drain chemical species, as are known in the art. The p type silicon portion 105 of the substrate 102 may comprise a PMOS gate 106 and PMOS source/drain regions 116,116′ which may comprise regions not yet implanted by PMOS chemical species, as are known in the art. Spacer material 119 may be disposed on lateral sides of the NMOS gate 118 and the PMOS gate 106. The spacer material 119 may comprise a dielectric material in some cases, such as but not limited to silicon dioxide and/or silicon nitride materials.

The p type silicon portion 105 may further comprise a BSR structure 108, wherein the BSR 108 may comprise a dielectric material 110 located on a top surface of a central top portion 114 of the BSR 108, and two endcap regions 112, 112′. The endcap regions 112, 112′ may comprise regions wherein a silicide may be subsequently formed. The dielectric material 110 may serve to mask the central portion 114 of the BSR 108 from silicidation, so that no silicide will be formed on the central portion 114 of the BSR 108. An STI region 104 may be disposed beneath the BSR 108.

In an embodiment, at least one of the PMOS and NMOS gates 106, 118 may comprise a metal gate. In an embodiment, the metal gate may comprise such metal gate materials as hafnium, zirconium, titanium, tantalum, or aluminum, or combinations thereof, for example. A resist material 122 may be formed on the n type silicon portion 103 of the substrate 102 (FIG. 1b). The resist material 122 serves to mask the n type diffusion areas (e.g. the NMOS gate 118, the NMOS source/drain regions 120) of the n type silicon portion of the substrate 102 from subsequent implant processing.

The structure 100 may be exposed to a PMOS source/drain implant 124, in an embodiment (FIG. 1c). Any suitable PMOS source/drain chemical species may be used to implant the structure 100 as are known in the art. During the PMOS source/drain implant 124, a portion of the PMOS source/drain regions 116, 116 may be implanted to form implanted PMOS source/drain regions 117. Further, during the PMOS source/drain implant 124, a portion 119 of the endcap regions 112, 112′ of the BSR 108 may be implanted with the PMOS chemical species. The exact dosage, energy and depth of the PMOS source/drain implant will vary according to the particular application.

The n type portion 103 of the substrate 102 remains masked by the resist 122, so that the NMOS gate 118 and NMOS source/drain regions 120 are not implanted by the PMOS chemical species during the PMOS source/drain implant process 124. While the resist 122 is left as a mask over the n type portion 103 of the substrate 102, the structure 100 may be exposed to a carbon species implant 126, in an embodiment (FIG. 1d). The carbon species may comprise any suitable carbon containing implant species, according to the particular embodiment. In an embodiment, the carbon implant 126 may be performed before an ash and clean process of the PMOS source/drain implant 124, in order to mitigate any carbon out-diffusion during following implant environments, as well as to minimize knock-on effects resulting in deficiency of carbon at surfaces.

The carbon species may be implanted into top portions 131 of the implanted PMOS source/drain regions 117, into top portions 129 of the PMOS gate 106 and into top portions 128 of the PMOS implanted endcap regions 119 of the BSR 108 (FIG. 1e). In an embodiment, the carbon species may be implanted into any p type structure that may be disposed on the p type portion 105 of the substrate 102. In an embodiment, the carbon species implant 126 energy may comprise between about 250 eV and about 750 eV, and a dose of the carbon species implant 126 may comprise above about 1 E15 ions/cm2. In other embodiments, the exact dosage, energy and depth of the carbon species implant 126 will vary according to the particular application.

Because the n type silicon portion 103 of the substrate 102 remains masked by the resist 122, the n type silicon portion 103 of the substrate 102 does not receive any implanting of the carbon species, e.g., the NMOS gate 118 and NMOS source/drain regions 120 do not comprise the carbon species in a top portion of the NMOS gate. In an embodiment, the implanting 126 of the carbon species into the structure 100 may comprise a shallow implant depth. In an embodiment, the carbon species may be disposed in a shallow region/depth 130 of a total depth 132 of the endcap region 112.

In an embodiment, the carbon species may comprise a depth of less than about 15 percent of the total depth 132 of the endcap regions. In some embodiments, the depth of the implanted carbon species may be optimized in order to minimize the interaction between carbon and other implant species in the p type portion 105 of the substrate 102.

The resist layer 122 may then be removed, and a salicide 134 may be formed on/in the NMOS gate 118, the NMOS source/drain regions 120, the carbon implanted PMOS source/drain regions 117 and the carbon implanted PMOS gate 106, and on the carbon implanted endcap regions 112, 112′ of the BSR 108, in a embodiment (FIG. 1f). Any suitable salicide/silicide process as are known in the art, such as but not limited to a nickel salicide process and/or other such salicide processes may be utilized. In some cases, carbon is known to degrade salicide formation, such as nickel salicide formation, for example, in n+diffusion and n+poly (such as in the NMOS gate and NMOS source/drain regions of the structure 100).

This may result in higher sheet resistance of the n+salicide, with larger variation, whereas it enhances the uniformity of salicide formation in p+poly (such as in the endcaps 112, 112′ of the BSR 108). Thus, improvement of the BSR silicide 134 uniformity is achieved without n+salicide degradation by using shallow carbon implant employed in a PMOS source-drain implant process, while masking the NMOS areas, according to the various embodiments of the present invention. FIG. 19 depicts a BSR matching plot comparing a BSR fabricated according to the embodiments of the present invention 140 to a prior art BSR 142. The lower slope for the BSR of the present invention 140 indicates improved BSR resistance matching.

Since the BSR 108 contains salicided endcaps at both ends, BSR matching behavior is strongly governed by the resistance matching of the salicide at the endcaps 112, 112′, especially when the thermal budget of salicide processing (rapid thermal anneal (RTA) etc.) for salicide formation, salicide anneal, etc. may be limited. Therefore, the more uniform salicide formation of the various embodiments greatly improves BSR resistance matching.

In prior art BSR structures, higher salicide anneal temperatures have been employed to improve the uniformity of BSR endcap salicides, but at the expense of more salicide patchiness in the other parts (for example, narrow and long p+salicide structures) of the product. Thicker silicides have also been applied to BSR structures to improve salicide uniformity, but this typically results in increased yield loss due to elevated salicide pipe occurrence. Embodiments of the present invention enable improved BSR resistance matching by carbon implanting in the PSD implant loop, utilizing the same thermal budget, while avoiding silicide deposition thickness increase. The blocked salicide resistor of the various embodiments is substantially free of pipes and patchy silicide.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic structures are well known in the art. Therefore, it is appreciated that the Figures provided herein illustrate only portions of exemplary microelectronic structures that pertain to the practice of the present invention. Thus the present invention is not limited to the structures described herein.

What is claimed is:

1. A method comprising:
implanting an exposed p type silicon portion of a substrate with a carbon species, wherein endcap regions of a blocked salicide resistor and a p type structure that are both disposed on the exposed p type silicon portion of the substrate are implanted with the carbon species.

2. The method of claim 1 further comprising forming a silicide on the endcap regions, wherein a resistance matching of the blocked silicide resistor is increased.

3. The method of claim 1 further comprising wherein a PMOS source/drain implant is performed on the endcap regions of the blocked salicide resistor and on the p type structure prior to the carbon species implant.

4. The method of claim 1 wherein the carbon species implant comprise a dose of greater than about 1 E15 ions/cm2.

5. The method of claim 1 further comprising wherein the blocked salicide resistor comprises a dielectric region in between the endcap regions.

6. The method of claim 1 further comprising wherein the energy of the carbon implant is between about 250 eV and 750 eV.

7. The method of claim 3 further comprising wherein the carbon implant is performed before an ash and clean process of the PMOS source/drain implant.

8. A method comprising:
masking an n-type silicon region disposed on a substrate, wherein a p type silicon region of the substrate is exposed;
implanting the p type silicon region with a source/drain implant, wherein an endcap region of a blocked salicide resistor disposed on the p type silicon region is implanted with the source/drain implant; and
implanting the p type silicon region with a carbon species, wherein the endcap region is implanted with the carbon species.

9. The method of claim 8 further comprising wherein the n-type silicon region comprises an NMOS transistor that is masked with resist and is not exposed to the PMOS implant and the carbon species implant.

10. The method of claim 8 further comprising wherein the p type silicon region comprises a PMOS transistor that is implanted with the source/drain implant and the carbon species implant.

11. The method of claim 8 further comprising wherein a silicide is formed on the endcaps of the blocked salicide resistor, wherein a uniformity of the salicide between the endcaps of the blocked salicide resistor is increased.

12. The method of claim 11 further comprising wherein the blocked salicide resistor comprising the silicide is substantially free of pipes and patchy silicide.

13. The method of claim 8 further comprising wherein the carbon species implant comprises a shallow implant.

14. A structure comprising:
a blocked salicide resistor disposed on a substrate, wherein endcap regions of the blocked salicide resistor comprise a carbon species.

15. The structure of claim 14 further comprising wherein the carbon species is disposed in a shallow region of the endcap region depth.

16. The structure of claim 14 further comprising wherein the carbon species comprises a depth of less than about 15 percent of a total depth of the endcap regions.

17. The structure of claim 14 wherein the blocked salicide resistor is disposed on a p type portion of the substrate, and wherein a p type structure comprises the carbon species in a top portion of the p type structure.

18. The structure of claim 14 further comprising wherein the substrate comprises an NMOS gate and a PMOS gate, wherein the PMOS gate comprises the carbon species in a top portion of the PMOS gate, and wherein the NMOS gate does not comprise the carbon species in a top portion of the NMOS gate.

19. The structure of claim 18 wherein the PMOS gate comprises a source/drain implant species, and wherein the endcap regions comprise the PMOS source/drain implant species.

20. The structure of claim 14 wherein the blocked salicide resistor comprises a silicide disposed on the endap regions, and wherein the resistance of the endcap silicides are resistance matched to each other.
